(19) United States
(12) Patent Application Publication
(10) Pub. No.: US 2016/0329228 A1
(43) Pub. Date: Nov. 10, 2016

(54) CASSETTE POSITIONING DEVICE AND SEMICONDUCTOR PROCESSING APPARATUS

(71) Applicant: BEIJING NMC CO. LTD., Beijing (CN)

(72) Inventors: Meng LI, Beijing (CN); Fenggang ZHANG, Beijing (CN); Peijun DING, Beijing (CN); Mengxin ZHAO, Beijing (CN); Feifei LIU, Beijing (CN); Wen ZHANG, Beijing (CN)

(73) Assignee: BEIJING NMC CO., LTD., Beijing (CN)

(21) Appl. No.: 15/108,493

(22) PCT Filed: Nov. 27, 2014
(86) PCT No.: PCT/CN14/92378

§ 371 Date: Jun. 27, 2016

(30) Foreign Application Priority Data
Dec. 27, 2013 (CN) 201310737644.4

(51) Int. Cl. H01L 21/677

(52) U.S. Cl. CPC H01L 21/67778; H01L 21/67775; H01L 21/67796

(57) ABSTRACT

The present invention provides a cassette positioning device and a semiconductor processing apparatus. The cassette positioning device includes: a positioning baseplate arranged horizontally and connected with the lifting device; a rotatable positioning, plate, which is located on the positioning baseplate, has one end rotatably connected with one end of the positioning baseplate, and is provided thereon with a positioning assembly; and a support column arranged under the rotatable positioning plate. The support column and the positioning baseplate can move relatively in the vertical direction, such that the rotatable positioning plate is pushed up by the support column and rotates to be inclined relatively to the positioning baseplate when the support column rises to a preset highest position relatively to the positioning baseplate, and the rotatable positioning plate and the positioning baseplate are stacked on the support column in parallel when the support column is located at a preset lowest position. In the cassette positioning device and the semiconductor processing apparatus, positions, in horizontal direction, of all the wafers in the cassette can be consistent, so that the wafers taken out by the mechanical arm can be located at uniquely specified positions on the mechanical arm.

### CROSS REFERENCE TO RELATED APPLICATION

This application claims the benefit of and priority to PCT/CN2014/092378 filed on Nov. 27, 2014, entitled (translation), “CASSETTE POSITIONING DEVICE AND SEMICONDUCTOR PROCESSING APPARATUS,” which claims the benefit of and priority to Chinese Patent Application No. 201310737644.4 filed on Dec. 27, 2013, entitled (translation), “CASSETTE POSITIONING DEVICE AND SEMICONDUCTOR PROCESSING APPARATUS,” both of which are hereby incorporated by reference in their entirety into this application.

### BACKGROUND

1. Field of the Invention

Embodiments of the invention relate to the field of microelectronics processing technology, and more particularly relate to a cassette positioning device and a semiconductor processing apparatus.

2. Description of the Related Art

Taking wafers out of a cassette is the first step in automatic transmission for multitudinous semiconductor processing apparatuses, and therefore, efficiency and reliability of wafer-taking become one of important and necessary conditions for realizing highly automated production of wafers.

FIG. 1 is a block diagram illustrating a principle of a conventional semiconductor processing apparatus, and FIG. 2 is a perspective view schematically illustrating a conventional structure of a cassette. As shown in FIGS. 1 and 2, the conventional semiconductor processing apparatus includes a loading chamber 13, a transfer chamber 2 and a reaction chamber 3. The loading chamber 13 is used for bearing a cassette 1, which is used for accommodating a plurality of wafers 6. A left side wall, a right side wall and a rear side wall (i.e., the three side walls at three sides, other than the side in the exit and entrance direction, of the cassette 1 in FIG. 2) inside the cassette 1 shown in FIG. 2 are each provided with slots for retaining the wafers 6, and the wafers 6 are retained in the horizontal direction by means of the slots on the left, right and rear side walls. A plurality of slots are arranged in a spaced manner on the left, right and rear side walls of the cassette 1 in the vertical direction, so that a plurality of wafers 6 can be provided in a spaced manner in the vertical direction in the cassette 1. In practical applications, the wafers 6 are taken out of or put into the cassette along the direction of the arrow in FIG. 2. A mechanical arm 4 used for transferring the wafers 6 between the cassette 1 and the reaction chamber 3 is provided in the transfer chamber 2. To enable the mechanical arm 4 to take any wafer 6 out of the cassette 1, a cassette lifting device 5 used for driving the cassette 1 to move linearly in the vertical direction is further provided at the bottom of the cassette 1.

In addition, a cassette positioning device, used for determining the horizontal position and levelness of the cassette 1, is further provided between the cassette 1 and the cassette lifting device 5. FIG. 3 is a perspective view of a conventional cassette positioning device. As shown in FIG. 3, the conventional cassette positioning device includes a positioning plate 7, which is fixed to a connecting plate 10 of the cassette lifting device 5 through screws 11 and used for bearing the cassette 1. Further, positioning stoppers 8 and a U-shaped positioning block 9, which are used for limiting horizontal movement of the cassette 1 when the cassette 1 is positioned on the positioning plate 7, are respectively provided on the positioning plate 7. Moreover, set screws 12, used for adjusting the levelness of the positioning plate 7, are further provided on the positioning plate 7. In the process of mounting the cassette 1, an operator places the cassette 1 on the positioning plate 7, restricts the horizontal position of the cassette 1 by using the positioning stoppers 8 and the U-shaped positioning block 9, and adjusts the levelness of the cassette 1 by using the set screws 12.

The following problem exists inevitably in the practical application of the conventional cassette positioning device, as described above. As shown in FIGS. 4A and 4B, in the conventional process of taking the wafers out of the cassette 1 using the mechanical arm 4, it is generally necessary to set a horizontal spacing A between the initial position center O1 of the mechanical arm 4 and the wafer-taking position center O2 in the cassette 1, and for each of the wafers 6 in the cassette 1, the horizontal spacing A is unique, so that it is ensured that each wafer 6 taken out by the mechanical arm 4 can be positioned at a uniquely specified position on the mechanical arm 4. However, because the operator places the cassette 1 on the positioning plate 7 manually, and this operation, due to factors such as speed, strength, angle or the like thereof, often causes the centers (at position of d/2 as shown in FIG. 4B, where d is the diameter of the wafer 6) of some wafers 6 in the cassette 1 to deviate from the wafer-taking position center O2, these wafers 6 will deviate from the uniquely specified positions on the mechanical arm 4 when taken out by the mechanical arm 4, and as a result, positions of different wafers 6 on the mechanical arm 4 are not unique, which can not only reduce the efficiencies of subsequent transfer and processes, but may also cause damage to the wafers 6.

In practical applications, although an additional wafer alignment device may be provided to cooperate with the mechanical arm to solve the problem of non-unique positions of different wafers on the mechanical arm, the cost of the wafer alignment device is high and the maintenance thereof is inconvenient. If the wafer alignment device is applied to a semiconductor processing apparatus, the manufacturing and use costs of the semiconductor processing apparatus will be increased.

### SUMMARY:

Embodiments of the invention address at least one of the technical problems existing in the prior art, and provide a cassette positioning device and a semiconductor processing apparatus, which can make positions, in the horizontal direction, of all the wafers in the cassette consistent, so that the wafers taken out by the mechanical arm are located at uniquely specified positions on the mechanical arm, and further the efficiencies of transfer and process are improved.

According to at least one embodiment, there is provided a cassette positioning device arranged in a loading chamber for accommodating a cassette and driven by a lifting device to move linearly in a vertical direction. The cassette positioning device includes a positioning baseplate, a rotatable positioning plate and a support column. According to an embodiment, the positioning baseplate is arranged horizontally and connected with the lifting device, and the rotatable positioning plate is arranged on the positioning baseplate, and has one end rotatably connected with one end of the positioning baseplate. According to an embodiment, the rotatable positioning plate is used for bearing the cassette, and provided thereon with a positioning assembly used for restricting position of the cassette on the rotatable positioning plate. According to an embodiment, the support column is arranged under the rotatable positioning plate, and the support column and the positioning baseplate are capable of moving relatively to each other in the vertical direction, such that the rotatable positioning plate is pushed up by the support column and rotates to be inclined relatively to the positioning baseplate when the support column rises to a preset highest position relatively to the positioning baseplate, and the rotatable positioning plate and the positioning baseplate are stacked in parallel on the support column when the support column is located at a preset lowest position.

According to at least one embodiment, the cassette positioning device further includes a rotary connection assembly, which includes a rotating shaft and a bearing which work cooperatively, wherein one of the rotating shaft and the bearing is fixedly connected to the positioning baseplate, the other one of the rotating shaft and the bearing is fixedly connected to the rotatable positioning plate, and central axes of both the rotating shaft and the bearing are parallel to a plane in which the positioning baseplate is located.

According to at least one embodiment, the cassette positioning device further includes two rotary connection assemblies, which are symmetrically arranged at two sides of one end of the positioning baseplate.

According to at least one embodiment, the support column is fixedly connected with the loading chamber.

According to at least one embodiment, the cassette positioning device further includes a support column lifting mechanism used for driving the support column to move linearly in the vertical direction.

According to at least one embodiment, the support column lifting mechanism includes a holder and a linear driving source, the holder is used for fixing the linear driving source to the bottom of the loading chamber; a lower end of the support column is connected with a drive shaft of the linear driving source; an upper end of the support column passes through the loading chamber in the vertical direction and extends to a position the rotatable positioning plate; and the linear driving source is used for driving the support column to move linearly in the vertical direction.

According to at least one embodiment, the linear driving source includes a linear motor or a linear cylinder.

According to at least one embodiment, the linear driving source is a linear cylinder, and the support column lifting mechanism further includes a buffer, which is used for decelerating and buffering the support column when the support column moves linearly in the vertical direction.

According to at least one embodiment, the support column lifting mechanism includes a holder, a rotary driving source and a transmission assembly, wherein the holder is used for fixing the rotary driving source to the bottom of the loading chamber; the rotary driving source is used for providing rotary power; the transmission assembly is used for converting the rotary power provided by the rotary driving source into linear power and transferring the linear power to the support column; a lower end of the support column is connected with the transmission assembly; and an upper end of the support column passes through the loading chamber in the vertical direction and extends to a position under the rotatable positioning plate.

According to at least one embodiment, the support column is sleeved with a bellows, which has an upper end connected with the bottom of the loading chamber in a sealed manner, and a lower end connected with the support column in a sealed manner.

According to at least one embodiment, the support column lifting mechanism further includes a guide post and a linear bearing which work cooperatively, the guide post has an upper end fixedly connected to the bottom of the loading chamber and is parallel to the vertical direction; and the linear bearing is connected with the support column.

According to at least one embodiment, there is further provided a semiconductor processing apparatus, including a loading chamber, a transfer chamber and a process chamber, wherein, the loading chamber is used for accommodating a cassette, and a lifting device is provided at the bottom of the loading chamber and is connected with the cassette and positioned through a cassette positioning device; and the transfer chamber is provided therein with a mechanical arm used for taking wafers out of or putting wafers into the cassette by cooperating with the lifting device, and transferring the wafers into or out of the process chamber, and the cassette positioning device is the cassette positioning device described herein for other embodiments of the invention.

### BRIEF DESCRIPTION OF THE DRAWINGS:

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a block diagram illustrating a principle of a conventional semiconductor processing apparatus.

FIG. 2 is a perspective view schematically illustrating a conventional structure of a cassette.

FIG. 3 is a perspective view of existing conventional cassette positioning device.

FIG. 4A is a top view illustrating a relative position between a mechanical arm and the cassette according to the conventional art.

FIG. 4B is a front view illustrating a relative position between the mechanical arm and the cassette according to the conventional art.

FIG. 5A is a perspective view of a cassette positioning device according to a first embodiment of the invention.

FIG. 5B is an enlarged diagram of region I in FIG. 5A according to the first embodiment of the invention.

FIG. 5C is a cross-sectional view of a rotary connection assembly according to the first embodiment of the invention.

FIG. 5D is a schematic diagram of the cassette positioning device in the case that the cassette is in an inclined state according to the first embodiment of the invention.

FIG. 5E is a schematic diagram of the cassette positioning device in the case that the cassette is in a horizontal state according to the first embodiment of the invention.

FIG. 6 is a cross-sectional view of another rotary connection assembly according to an embodiment of the invention.

FIG. 7A a schematic diagram of a cassette positioning device according to a second embodiment of the invention.

FIG. 7B is an enlarged diagram of region II in FIG. 7A according to the second embodiment of the invention.

FIG. 8 is a schematic diagram of another support column lifting mechanism according to an embodiment of the invention.

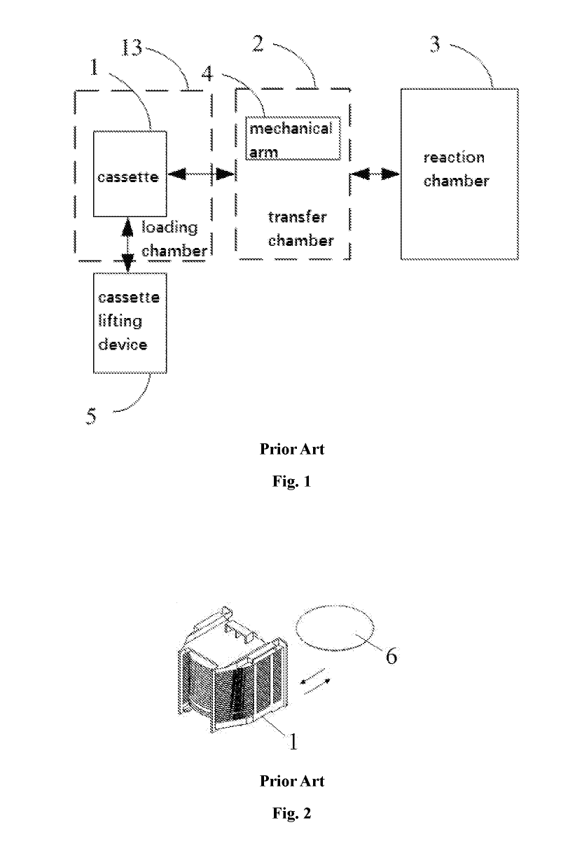

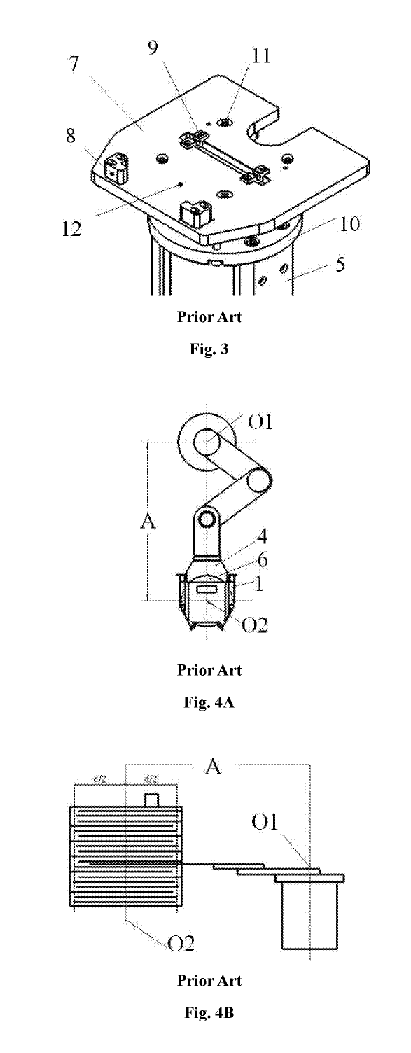

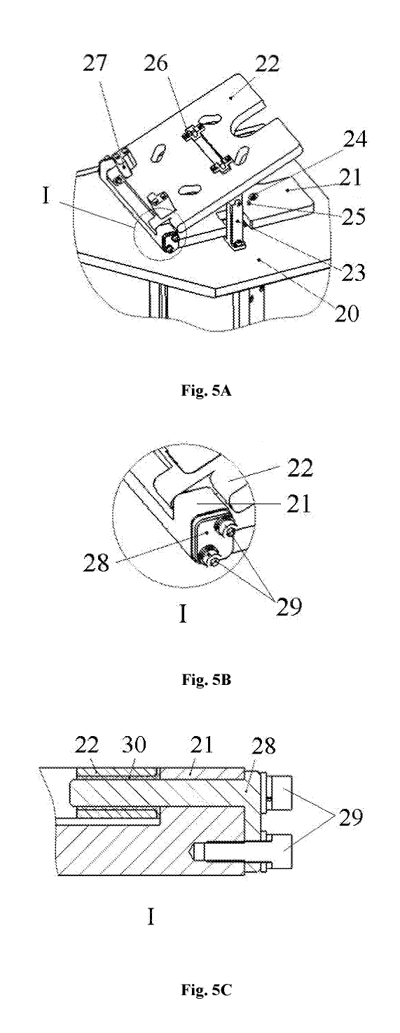

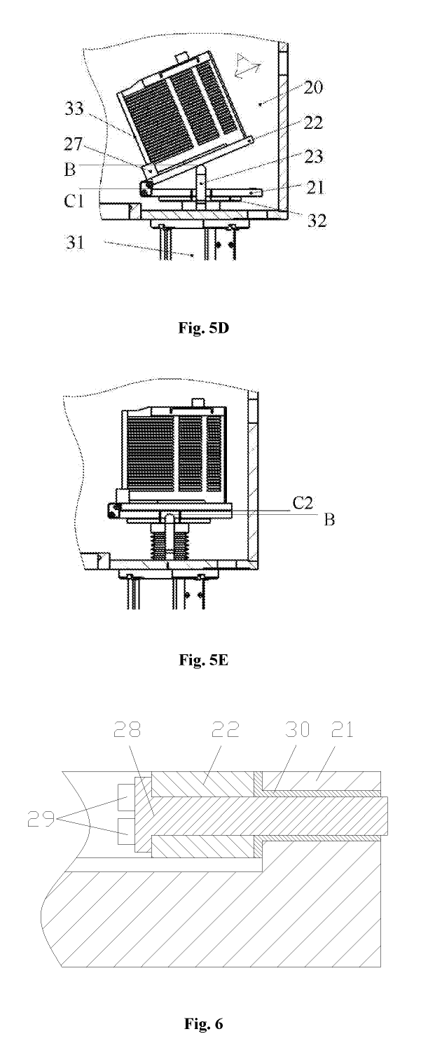

### DETAILED DESCRIPTION:

Advantages and features of the invention and methods of accomplishing the same will be apparent by referring to embodiments described below in detail in connection with the accompanying drawings. However, the invention is not limited to the embodiments disclosed below and may be implemented in various different forms. The embodiments are provided only for completing the disclosure of the invention and for fully representing the scope of the invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. According to at least one embodiment, the dimensions of some of the elements in the figures may be exaggerated relative to other elements to help improve understanding of embodiments of the invention. Like reference numerals refer to like elements throughout the specification.

To give those skilled in the art a better understanding of technical solutions of the present invention, a cassette positioning device and a semiconductor processing apparatus provided by various embodiments of the invention will be described in detail below in conjunction with the accompanying drawings.

### First Embodiment

Referring to FIGS. 5A to 5E, a first embodiment of the invention provides a cassette positioning device, which is arranged in a loading chamber 20 for accommodating a cassette 33 and driven by a lifting device 31 to move linearly in the vertical direction to cooperate with a mechanical arm (not shown in the figures) to take a wafer out of or put a wafer into the cassette 33.

According to at least one embodiment, the cassette positioning device includes a positioning baseplate 21, a rotatable positioning plate 22, and a support column 23. The positioning baseplate 21 is arranged horizontally and connected with the lifting device 31. In the present embodiment, the lifting device 31 has a connecting plate 32 horizontally provided at the top thereof, and the positioning baseplate 21 is connected and fixed to the connecting plate 32 through screws 34 and thus connected with the lifting device 31. Preferably, the positioning baseplate 21 is further provided thereon with a levelness adjusting screw 25 used for adjusting the levelness of the positioning baseplate 21.

According to at least one embodiment, the rotatable positioning plate 22 is arranged on the positioning baseplate 21, has one end rotatably connected with one end of the positioning baseplate 21, and is used for bearing the cassette 33. Further, the rotatable positioning plate 22 is provided thereon with a positioning assembly used for restricting the position of the cassette 33 on the rotatable positioning plate 22.

According to at least one embodiment, the rotatable positioning plate 22 and the positioning baseplate 21 are connected in such a manner that one end of the rotatable positioning plate 22 is rotatably connected with one end of the positioning baseplate 21 through a rotary connection assembly. As shown in FIG. 5A, there are two rotary connection assemblies which are symmetrically arranged at two sides of one end of the positioning baseplate 21. As shown in FIG. 5C, each rotary connection assembly includes a rotating shaft 28 and a bearing 30, which work cooperatively, and the rotating shaft 28 is fixedly connected to the positioning baseplate 21 and is parallel to the horizontal direction. Specifically, on an upper surface of the positioning baseplate 21, two first protrusions are provided at two sides of one end (left end) of the positioning baseplate 21, respectively, and each first protrusion is provided therein with a first through hole penetrating through the thickness thereof in the horizontal direction. Accordingly, on the end surface (left end) of the rotatable positioning plate 22, two second protrusions are provided at positions close to the inner sides of the two first protrusions, respectively, each second protrusion is provided therein with a second through hole penetrating the thickness thereof in the horizontal direction, and the first though holes and the second through holes are coaxially arranged. For each rotary connection assembly, the rotating shaft 28 sequentially passes through the first through hole and the second through hole, and has an end (right end) fixedly connected to the first protrusion through two screws 29. The bearing 30 holds the rotating shaft 28 therein, is located in the second through hole, and is fixedly connected with the rotatable positioning plate 22.

In practical applications, the following connection manner may be adopted to rotatably connect one end of the rotary positioning plate 22 with one end of the positioning baseplate 21 through the rotary connection component. Specifically, as shown in FIG. 6, this connection manner differs from the above-described manner in that: the rotating shaft 28 is fixedly connected with the rotatable positioning plate 22 and parallel to the horizontal direction; the bearing 30 is fixedly connected with the positioning baseplate 21, and in this manner, one end of the rotatable positioning plate 22 can also be rotatably connected with one end of the positioning baseplate 21. The specific connection manner is similar to that shown in FIGS. 5A to 5E, and is not repeated herein. In addition, other connection manner in which one end of the rotatable positioning plate 22 can be rotatably connected with one end of the positioning baseplate 21 may also be adopted.

According to at least one embodiment, the support column 23 is provided under the rotatable positioning plate 22, and is fixedly connected with the loading chamber 20. Specifically, as shown in FIG. 5D, a lower end of the support column 23 is fixedly connected with the bottom wall of the loading chamber 20, the positioning baseplate 21 is provided therein with a through hole through which the support column 23 can pass, and an upper end of the support column 23 passes through the through hole along the vertical direction and extends upwards to a position which is under the rotatable positioning plate 22. When the lifting device 31 drives the positioning baseplate 21 to move linearly in the vertical direction, the support column 23 and the positioning baseplate 21 move relatively to each other along a straight line in the vertical direction, that is, the positioning baseplate 21 drives the rotatable positioning plate 22 to rise or fall relatively to the loading chamber 20, while the support column 23 is relatively static to the loading chamber 20.

As shown in FIGS. 5D and 5E, the top end of the support column 23 is always located at position B in the vertical direction, while the upper surface of the positioning baseplate 21, driven by the lifting device 31, may falls to position Cl in the vertical direction, or rises to position C2 in the vertical direction. Before wafers need to be loaded into the cassette 33, the positioning baseplate 21 is driven by the lifting device 31 to fall to position Cl, at this time, the rotatable positioning plate 22 is pushed up by the support column 23 and rotates to be inclined relative to the positioning baseplate 21, so that the cassette 23 can be inclined (as shown in FIG. 5D, the front end, for wafer-taking, of the cassette 33 is inclined upwardly, and the wafer-taking or wafer-putting direction is shown by A in the figure), when the operator puts the cassette 3 on the rotatable positioning plate manually, further, the wafers in the cassette 33, under the action of gravity thereof, automatically slide into the slots at the rear end of the cassette 33, and thus positions, in the horizontal direction, of all the wafers in the cassette 33 are consistent. Afterward, the positioning baseplate 21 is driven by the lifting device 31 to rise to position C2, at this time, the top end of the support column 23 falls relatively to the upper surface of the positioning baseplate 21, to a position lower than the upper surface of the positioning baseplate 21, so that the included angle between the rotatable positioning plate 22 and the positioning baseplate 21 is gradually reduced to zero, that is, the rotatable positioning plate 22 gradually falls back onto the positioning baseplate 21. In this way, positions, in the horizontal direction, of all the wafers in the cassette 33 are consistent, and thus the wafers each are located at a uniquely specified position on the mechanical arm when taking the wafers by the mechanical arm. Therefore, there is no need to repeatedly adjust the position of the mechanical arm in order to accurately take one wafer, thereby improving the efficiencies of transfer and processes; further, the case that a wafer falls off or is damaged due to improper position of the wafer on the mechanical arm is avoided.

In practical applications, the above position Cl may be set according to the inclined angle of the rotatable positioning plate 22 relative to the positioning baseplate 21, i.e., according to the preset highest position which the support column 23 can reach when rising relatively to the positioning baseplate 21. Similarly, the above position C2 should be set such that it is ensured that the support column 23 falls, relatively to the positioning baseplate 21, to the preset lowest position, and at the preset lowest position, the top end of the support column 23 is lower than the upper surface of the positioning baseplate 21.

According to at least one embodiment, the positioning assembly includes the U-shaped positioning block 26 and two positioning stoppers 27 provided on the rotatable positioning plate 22, and is used for limiting horizontal movement of the cassette 33 after the cassette 33 is placed on the rotatable positioning plate 22, and preventing the cassette 33 from sliding relatively to the rotatable positioning plate 22 when the rotatable positioning plate 22 is inclined. Needless to say, in practical applications, the positioning assembly with any other structure may be adopted, as long as horizontal movement of the cassette 33 can be limited after the cassette 33 is placed on the rotatable positioning plate 22.

It should be noted that, in accordance with this embodiment, there are two rotary connection assemblies symmetrically provided at two sides of one end of the positioning baseplate 21, in this way, the rotatable positioning plate 22 can be stably pushed up by the support column 23 to improve structure stability of the cassette positioning device. Needless to say, in practical applications, the number of the rotary connection assembly/assemblies may be set to be one, or more than three, according to the specific condition.

### Second Embodiment

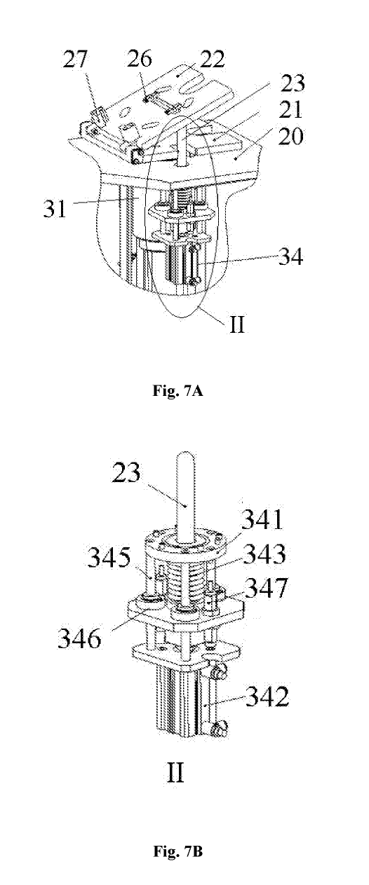

FIG. 7A is a schematic diagram of a cassette positioning device according to a second embodiment of the invention. FIG. 7B is an enlarged diagram of region II in FIG. 7A according to the second embodiment of the invention. Referring to FIGS. 7A and 7B, the cassette positioning device also includes a positioning baseplate 21, a rotatable positioning plate 22 and a support column 23. The positioning baseplate 21, the rotatable positioning plate 22 and the support column 23 have the same functions and structures as those in the above first embodiment, which are not repeated here. Only the differences between the present embodiment and the above first embodiment will be described in detail below.

Specifically, the cassette positioning device further includes a support column lifting mechanism 34 used for driving the support column 23 to move linearly in the vertical direction. In this case, the support column 23 may be driven by the support column lifting mechanism 34 to move linearly in the vertical direction when the positioning baseplate 21 is relatively static to the loading chamber 20, so that when the top end of the support column 23 rises to a position higher than the upper surface of the positioning baseplate 21, the support column 23 pushes up the rotatable positioning plate 22 to cause the rotatable positioning plate 22 to rotate to be inclined relatively to the positioning baseplate 21, thus making the cassette 33 on the rotatable positioning plate 22 inclined. As the top end of the support column 23 gradually falls to a position lower than the upper surface of the positioning baseplate 21, the included angle between the rotatable positioning plate 22 and the positioning baseplate 21 is gradually decreased to zero, and accordingly, the rotatable positioning plate 22, under the action of gravity thereof, gradually falls back onto the positioning baseplate 21. It can be easily understood that, the positioning baseplate 21 keeps relatively static to the loading chamber 20 during the rising and falling processes of the support column 23.

The structure of the support column lifting mechanism will be described in detail below in conjunction with FIG. 7B. Specifically, the support column lifting mechanism includes a holder 341 and a linear driving source 342. The holder 341 is used for fixing the linear driving source 342 to the bottom of the loading chamber 20. The lower end of the support column 23 is connected with a drive shaft of the linear driving source 342, a through hole is provided at the bottom of the loading chamber 20, and the support column 23 enters into the interior of the loading chamber 20 via the through hole and extends to a position which is under the rotatable positioning plate 22. The linear driving source 342 is used for driving the support column 23 to move linearly in the vertical direction. The linear driving source 342 includes a linear motor or a linear cylinder.

Preferably, in accordance with at least one embodiment, the linear driving source 342 is a linear cylinder, and in order to improve motion stability of the support column 23, the support column lifting mechanism further includes a buffer 347 for decelerating and buffering the support column 23 when the support column 23 moves linearly in the vertical direction.

Further preferably, the support column 23 is sleeved with a bellows 343, the upper end of the bellows 343 is connected with the bottom of the loading chamber 20 in a sealed manner, and the through hole via which the support column 23 enters into the loading chamber 20 is located in the bellows 343. The lower end of the bellows 343 is connected with the support column 23 in a sealed manner. By means of the bellows 343, the loading chamber 20 can be sealed to ensure a vacuum state therein.

Further preferably, the support column lifting mechanism further includes guide posts 345 and linear bearings 346 which cooperate with each other. Each linear bearing 346 is fixedly connected with the support column 23 via a fixing member such as a flange. Each guide post 345 has an upper end fixedly connected to the bottom of the loading chamber 20 and a lower end which passes through the linear bearing 346 and can move relatively to the linear bearing 346 in the vertical direction. When the linear driving source 342 drives the support column 23 to move, the linear bearings 346 are driven by the support column 23 to slide along the guide posts 345 to guide the support column 23 to move linearly in the vertical direction.

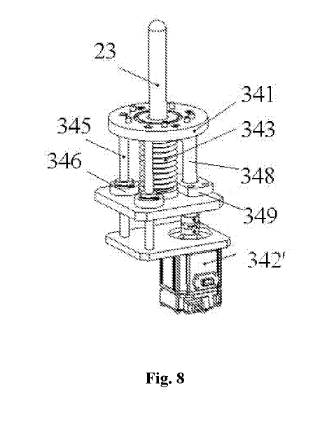

It should be noted that, in accordance with at least one embodiment, the linear driving source 342 serves as the power source of the support column lifting mechanism, but the present invention is not limited thereto. In practical applications, a rotary driving source may also be adopted as the power source, and specifically, as shown in FIG. 8, the support column lifting mechanism includes: a holder 341, a rotary driving source 342′ and transmission assembly. The holder 341 is used for fixing the rotary driving source 342′ to the bottom of the loading chamber 20, the rotary driving source 342′ is used for providing rotary power, and the transmission assembly is used for converting the rotary power provided by the rotary driving source 342′ into linear power and transferring the linear power to the support column 23. The lower end of the support column 23 is connected with the transmission assembly, a through hole is provided at the bottom of the loading chamber 20, and the upper end of the support column 23 passes through the loading chamber 20 in the vertical direction via the through hole and extends to a position which is under the rotatable positioning plate 22.

According to at least one embodiment, the transmission assembly includes a screw 348 and a nut 349, which work cooperatively with threads of the screw 348, and the screw 348 is connected with the drive shaft of the rotary driving source 342′, the nut 349 is connected with the lower end of the support column 23, the screw 348 is driven by the rotary driving source 342′ to rotate, and drives the nut 349 through the threads to move linearly in the vertical direction so that the support column 23 rises or falls simultaneously. Preferably, a guide post 345 and a linear bearing 346, which work cooperatively, may also be provided to guide the support column 23.

According to another embodiment, there is provided a semiconductor processing apparatus, which includes a loading chamber, a transfer chamber and a process chamber. The loading chamber is used for accommodating a cassette, and a lifting device is provided at the bottom of the loading chamber and is connected to the cassette and positioned through a cassette positioning device. The transfer chamber is provided therein with a mechanical arm used for taking out or putting in wafers by cooperating with the lifting device. The cassette positioning device may be the cassette positioning device provided in the above described embodiments.

In the cassette positioning device according to various embodiments of the invention, by rotatably connecting one end of the rotatable positioning plate with one end of the positioning baseplate, and allowing the support column arranged under the rotatable positioning plate to move relatively to the positioning baseplate in the vertical direction, when the support column rises to a preset highest position, the rotatable positioning plate can be pushed up by the support column and rotates to be inclined relatively to the positioning baseplate, so that the cassette can be inclined (i.e., the front end, for wafer taking, of the cassette is inclined upwardly) after the operator places the cassette on the rotatable positioning plate manually, then the wafers in the cassette can automatically slide into the slots at the rear side of the cassette under the action of gravity, and thus positions, in the horizontal direction, of all the wafers in the cassette have are consistent; afterwards, when the support column is located at a preset lowest position, the rotatable positioning plate falls back onto the positioning baseplate, and at this time, the wafers taken out by the mechanical arm can all be located at uniquely specified positions on the mechanical arm, thereby improving efficiencies of transfer and process, and reducing damage to the wafers.

In the semiconductor processing apparatus provided by an embodiment of the invention, by adopting the above cassette positioning device described above for various embodiments of the invention, positions, in the horizontal direction, of all the wafers in the cassette can be consistent, so that the wafers taken out by the mechanical arm can be located at uniquely specified positions on the mechanical arm, thereby improving efficiencies of transfer and process, and preventing damage to the wafers.

Terms used herein are provided to explain embodiments, not limiting the invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the invention may suitably comprise, consist or consist essentially of the elements disclosed and may be practiced in the absence of an element not disclosed. According to at least one embodiment, it can be recognized by those skilled in the art that certain steps can be combined into a single step.

The terms and words used in the specification and claims should not be interpreted as being limited to typical meanings or dictionary definitions, but should be interpreted as having meanings and concepts relevant to the technical scope of the invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

It can be understood that, the above implementations are merely exemplary implementations used for explaining the principle of the embodiments of the invention, but the present invention is not limited thereto. For those skilled in the art, various modifications and improvements may be made without departing from the spirit and essence of the present invention, and these modifications and improvements are also deemed as falling within the protection scope of the embodiments of the invention.

1. A cassette positioning device arranged in a loading chamber for accommodating a cassette and driven by a lifting device to move linearly in a vertical direction, the cassette positining device comprising:
a positioning baseplate;
a rotatable positioning plate; and
a support column,
wherein the positioning baseplate is arranged horizontally and connected with the lifting device,
wherein the rotatable positioning plate is located on the positioning baseplate, and has one end rotatably connected with one end of the positioning baseplate, the rotatable positioning plate being used for bearing the cassette, and is provided thereon with a positioning assembly used for restricting position of the cassette on the rotatable positioning plate, and
wherein the support column is arranged under the rotatable positioning plate, and the support column and the positioning baseplate are capable of moving relatively to each other in the vertical direction, such that the rotatable positioning plate is pushed up by the support column and rotates to be inclined relatively to the positioning baseplate when the support column rises to a preset highest position relatively to the positioning baseplate, and the rotatable positioning plate and the positioning baseplate are stacked on the support column in parallel when the support column is located at a preset lowest position.

2. The cassette positioning device according to claim 1, further comprising;
a rotary connection assembly comprising a rotating shaft and a bearing which work cooperatively,
wherein one of the rotating shaft and the bearing is fixedly connected to the positioning baseplate, the other one of the rotating shaft and the bearing is fixedly connected to the rotatable positioning plate, and central axes of both the rotating shaft and the bearing are parallel to a plane in which the positioning baseplate is located.

3. The cassette positioning device according to claim 2, further comprising:
two rotary connection assemblies symmetrically arranged at two sides of one end of the positioning baseplate.

4. The cassette positioning device according to claim 1, wherein the support column is fixedly connected with the loading chamber.

5. The cassette positioning device according to claim 1, further comprising:
a support column lifting mechanism used for driving the support column to move linearly in the vertical direction.

6. The cassette positioning device according to claim 5, wherein the support column lifting mechanism comprises a holder and a linear driving source, the holder i-s-being used for fixing the linear driving source to the bottom of the loading chamber,
wherein a lower end of the support column is connected with a drive shaft of the linear driving source,
wherein an upper end of the support column passes through the loading chamber in the vertical direction and extends to a position under the rotatable positioning plate, and
wherein the linear driving source is used for driving the support column to move linearly in the vertical direction.

7. The cassette positioning device according to claim 6, wherein the linear driving source comprises a linear motor or a linear cylinder.

8. The cassette positioning device according to claim 7, wherein the linear driving source is a linear cylinder, and the support column lifting mechanism further comprises a buffer used for decelerating and buffering the support column when the support column moves linearly in the vertical direction.

9. The cassette positioning device according to claim 5, wherein the support column lifting mechanism comprises a holder, a rotary driving source and a transmission assembly, the holder being used for fixing the rotary driving source to the bottom of the loading chamber,
wherein the rotary driving source is used for providing rotary power,
wherein the transmission assembly is used for converting the rotary power provided by the rotary driving source into linear power and transferring the linear power to the support column, and
wherein a lower end of the support column is connected with the transmission assembly, and an upper end of the support column passes through the loading chamber in the vertical direction and extends to a position under the rotatable positioning plate.

10. The cassette positioning device according to claim 6 or 9, wherein the support column is sleeved with a bellows, which has an upper end connected with the bottom of the loading chamber in a sealed manner, and a lower end connected with the support column in a sealed manner.

11. The cassette positioning device according to claim 6 or 9, wherein the support column lifting mechanism further comprises a guide post and a linear bearing which work cooperatively, the guide post having an upper end fixedly connected to the bottom of the loading chamber and being parallel to the vertical direction, and the linear bearing being connected with the support column.

12. A semiconductor processing apparatus, comprising;
a loading chamber;
a transfer chamber, and
a process chamber,
wherein the loading chamber is used for accommodating a cassette, and a lifting device is provided at the bottom of the loading chamber and is connected with the cassette and positioned through a cassette positioning device,
wherein the transfer chamber is provided therein with a mechanical arm used for taking wafers out of or putting wafers into the cassette by cooperating with the lifting device, and transferring the wafers into or out of the process chamber, and
wherein the cassette positioning device is the cassette positioning device according to claim 1.
